(19) United States
(12) Patent Application Publication
(10) Pub. No.: US 2012/0170219 A1
(43) Pub. Date: Jul. 5, 2012

(54) ELECTRONIC DEVICE

(75) Inventors: KANG WU, Shenzhen City (CN); BO TIAN, Shenzhen City (CN); XIAO-GANG YIN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/048,880

(22) Filed: Mar. 16, 2011

(30) Foreign Application Priority Data
Dec. 31, 2010 (CN) 201010618167.6

(51) Int. Cl. H05K 7/20

(52) U.S. Cl. 361/695

(57) ABSTRACT

An electronic device includes a chassis, a fixing plate, and a fan. The chassis includes a sidewall defining an opening. The fixing plate is detachably fixed to an outer side of the sidewall, to cover the opening. The fan is detachably fixed to an inner side of the fixing plate, and received in the chassis through the opening.

### BACKGROUND

1. Technical Field

The present disclosure relates to an electronic device.

2. Description of Related Art

Typically, a fan is mounted in a chassis of an electronic device, to dissipate heat for the electronic device. However, when there is a need to repair or replace the fan, the chassis must be opened, which is troublesome.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawing, all the views are schematic, and like reference numerals designate corresponding parts throughout the several views.

FIG. 1 is an exploded, isometric view of an embodiment of an electronic device.

FIG. 2 is an assembled, isometric view of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

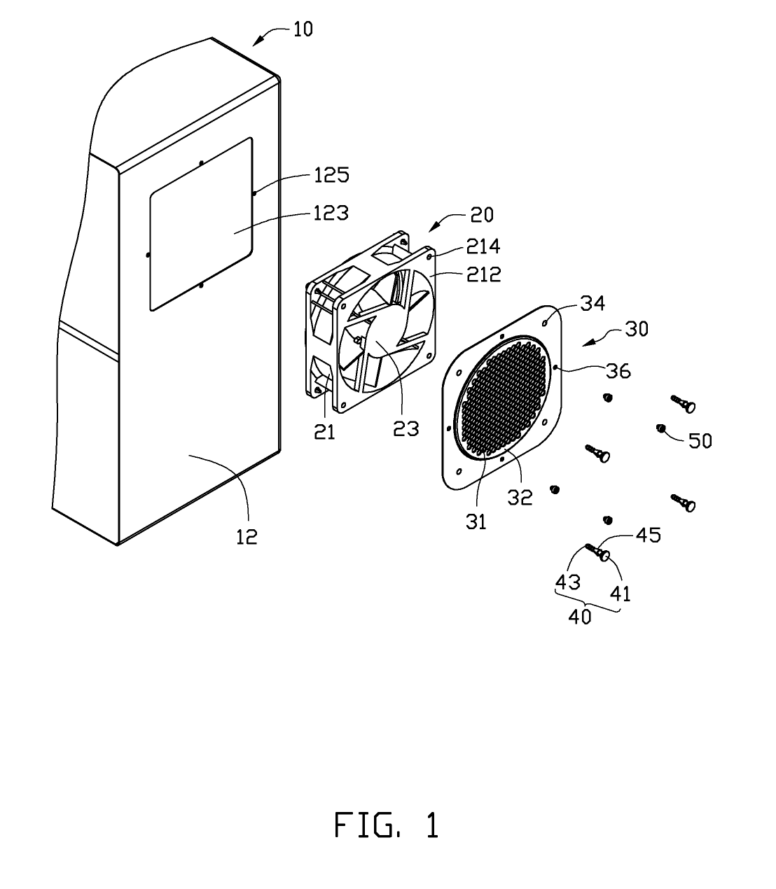

Referring to FIG. 1, an embodiment of an electronic device includes a chassis 10, a fan 20, a fixing plate 30, four first fasteners 40, and a plurality of second fasteners 50.

The chassis 10 includes a sidewall 12. An opening 123 is defined in the sidewall 12, and a plurality of fixing holes 125 is defined in the sidewall 12 around the opening 123.

The fan 20 includes a frame 21 and an impeller 23 installed in the frame 21. The frame 21 includes two spaced square mounting plates 212. Four through holes 214 are respectively defined in four corners of each mounting plate 212.

A circular ventilation area 32 defining a plurality of vents 31 is formed on a middle area of the fixing plate 30. Four through holes 34 are defined in the fixing plate 30 around the ventilation area 32 corresponding to the through holes 214 of one of the mounting plates 212 of the fan 20. A plurality of fixing holes 36 is defined in the fixing plate 30 corresponding to the fixing holes 125 of the sidewall 12 of the chassis 10.

Each first fastener 40 includes a head 41 and a post 43 perpendicularly extending from a side of the head 41. A substantially tapered resilient flange 45 extends outwardly from a circumference of the post 43 adjacent to the head 41. A diameter of the flange 45 gradually decreases along a direction away from the head 41.

In this embodiment, the second fasteners 50 are screws.

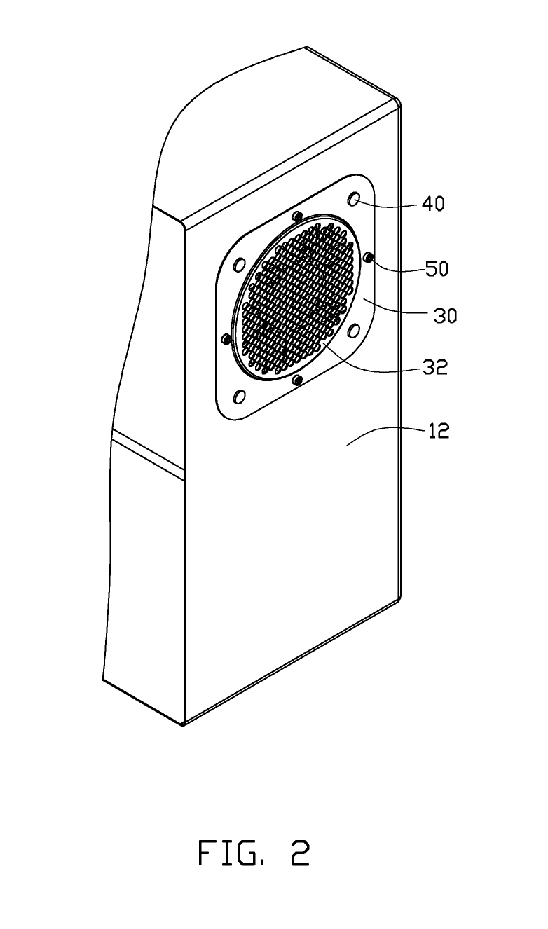

Referring to FIG. 2, in assembly, the fixing plate 30 is arranged to abut against one of the mounting plates 212 of the fan 20, with the through holes 34 of the fixing plate 30 aligning with the through holes 214 of the mounting plate 212, respectively. The posts 43 of the first fasteners 40 are correspondingly extended through the through holes 34 and 214 of the fixing plate 30 and the abutting mounting plate 212. The heads 41 of the first fasteners 40 are pressed towards the fixing plate 34, to allow the flanges 45 of the first fasteners 40 to deform and extend through the corresponding through holes 34 and 214 of the fixing plate 30 and the abutting mounting plate 212. The flanges 45 of the first fasteners 40 are then restored after extending through the through holes 214, and the fixing plate 30 and the abutting mounting plate 212 are sandwiched between the heads 41 and the flanges 45 of the first fasteners 40. Thereby, the fan 20 is fixed to the fixing plate 30. The ventilation area 32 of the fixing plate 30 is aligned with the impeller 23 of the fan 20. A cable (not shown) of the fan 20 is extended through the opening 123 of the chassis 10 and electrically connected to a circuit board (not shown) in the chassis 10. The fan 20 is inserted into the chassis 10 through the opening 123 of the sidewall 12. The fixing plate 30 is blocked out of the chassis 10 by the sidewall 12, with the fixing holes 36 of the fixing plate 30 aligning with the fixing holes 125 of the sidewall 12, respectively. The second fasteners 50 are respectively extended through the fixing holes 36 of the fixing plate 30 and then engage in the corresponding fixing holes 125 of the sidewall 12. Thereby, the fan 20 and the fixing plate 30 are fixed to the sidewall 12 of the chassis 10.

To detach the fan 20 from the chassis 10, the second fasteners 50 are disengaged from the sidewall 12 and the fixing plate 30. The fixing plate 30 is pulled outward, to take the fan 20 out of the chassis 10 through the opening 123. Because the fasteners 50 need only extend through one side of the fan 20, the fasteners 50 are short and easy to work with and save on material. And having only to detach the fixing plate 30 to access the fan 20 or the interior space of the chassis 10 makes servicing content of the chassis 10 a simple and convenient process.

It is to be understood, however, that even though numerous characteristics and advantages of the embodiments have been set forth in the foregoing description, together with details of the structure and function of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. An electronic device, comprising:
a chassis comprising a sidewall, the sidewall defining an opening therein;
a fixing plate detachably fixed to an outer side of the sidewall to cover the opening; and
a fan detachably fixed to an inner side of the fixing plate and received in the chassis through the opening.

2. The electronic device of claim 1, wherein the fan comprises a frame and an impeller installed in the frame, a ventilation area defining a plurality of vents is formed on a middle area of the fixing plate and aligns with the impeller of the fan.

3. The electronic device of claim 2, wherein the frame comprises a mounting plate defining a plurality of first through holes around the impeller, a plurality of second through holes is defined in the fixing plate around the ventilation area, a plurality of first fasteners is extended through the second through holes of the fixing plate and engages in the first through holes of the fan, respectively.

4. The electronic device of claim 3, wherein each of the first fasteners comprises a head and a post extending from a side of the head, a substantially tapered resilient flange extends outwardly from a circumference of the post adjacent to the head, a diameter of the flange gradually decreases along a direction away from the head, the posts of the first fasteners are extended through the second and first through holes of the fixing plate and the mounting plate, and the fixing plate and the mounting plate are sandwiched between the heads and the flanges of the first fasteners.

5. The electronic device of claim 1, wherein a plurality of first fixing holes is defined in the sidewall around the opening, and a plurality of second fixing holes is defined in the fixing plate corresponding to the first fixing holes of the sidewall, a plurality of second fasteners is extended through the second fixing holes of the fixing plate and engages in the first fixing holes of the sidewall, respectively.
